(19) United States
(12) Patent Application Publication
(10) Pub. No.: US 2018/0273840 A1
(43) Pub. Date: Sep. 27, 2018

(54) SPIRALLY CONFIGURED CIS-STILBENE/FLUORENE HYBRID MATERIAL AND ORGANIC ELECTROLUMINESCENT DEVICE USING THE SAME

(71) Applicant: CLIPHOR TECHNOLOGY CO., LTD., Taipei City (TW)

(72) Inventor: Chien-Tien CHEN, Taipei City (TW)

(21) Appl. No.: 15/605,439

(22) Filed: May 25, 2017

(30) Foreign Application Priority Data
Mar. 24, 2017 (TW) 106110032

(51) Int. Cl. C09K 11/06

(52) U.S. Cl. CPC C09K 11/06; H01L 51/5056

(57) ABSTRACT

A spirally configured cis-stilbene/fluorene hybrid material is shown in formula (1),

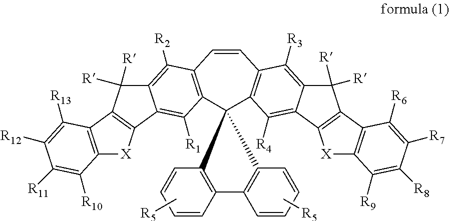

wherein R′ is an alkyl group or represented by formula (2), X represents CR₃₆R₃₇ or NR₃₈, wherein R₃₆ is represented by formula (3), R₃₇ is represented by formula (4), R₃₈ is represented by formula (5),

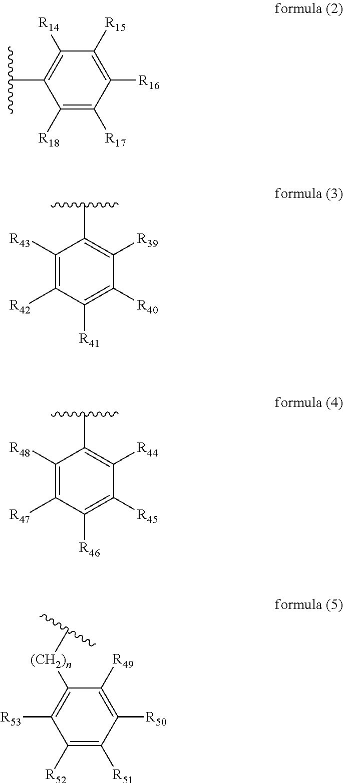

wherein R₁ to R₄, R₆ to R₁₈ and R₃₉ to R₅₃ are independently selected from the group consisting of hydrogen atom, halogen atom, cyano group, alkyl group, cycloalkyl group, alkoxy group, amino group, haloalkyl group, thioalkyl group, silyl group and alkenyl group, R₅ is a hydrogen atom, tert-butyl group or naphthyl group, n is 0 or 1.

### CROSS REFERENCE TO RELATED APPLICATIONS

This Non-provisional application claims priority under 35 U.S.C. § 119(a) on Patent Application No(s). 106110032 filed in Taiwan, Republic of China on Mar. 24, 2017, the entire contents of which are hereby incorporated by reference.

### BACKGROUND OF THE INVENTION

### Field of Invention

The present invention relates to a material and an electroluminescent device by using the same and, in particular, to a spirally configured cis-stilbene/fluorene hybrid material and an organic electroluminescent device by using the same.

### Related Art

With the advances in electronic technology, a light weight and high efficiency flat display device has been developed. An organic electroluminescent device becomes the mainstream of the next generation flat panel display device due to its advantages of self-luminosity, no restriction on viewing angle, low power conservation, simple manufacturing process, low cost, high response speed, full color and so on.

In general, the organic electroluminescent device includes an anode, an organic luminescent layer and a cathode. When applying a direct current to the organic electroluminescent device, holes and electrons are injected into the organic luminescent layer from the anode and the cathode, respectively. Charge carriers move and then transport into the organic luminescent materials because of the potential difference caused by an applied electric field. The resulting excited luminescent molecules (i.e., excitons) are generated and followed by the recombination of the electrons and the holes may lead to emission in the organic luminescent layer due to release the energy in the form of light.

Nowadays, the organic electroluminescent device usually adopts a host-guest emitter system. The organic luminescent layer disposed therein includes a host material and a guest material. The holes and the electrons are transmitted to the host material, and further transferred to the guest material to form excitons and then generate light. The guest material can be categorized into fluorescent material and phosphorescent material. Theoretically, the internal quantum efficiency can approach 25% by using appropriate fluorescent materials. Comparing with the phosphorescent materials, the fluorescent materials have longer shelf and device lifespan and lower cost.

Besides, the selection of organic electroluminescent material is not only based on the matching of HOMO and LUMO energy levels but also counts on high temperature of decomposition in order to avoid pyrolysis during thermal vacuum deposition and also thus avoid the decrease in thermal stability.

Accordingly, the present invention is provided a spirally configured cis-stilbene/fluorene hybrid material and an organic electroluminescent device by using the same which has excellent electronic, optical, and optoelectronic properties and thermal stability.

### SUMMARY OF THE INVENTION

In view of the foregoing objectives, the invention provides a spirally configured cis-stilbene/fluorene hybrid material and an organic electroluminescent device by using the same. The spirally configured cis-stilbene/fluorene hybrid material has excellent electronic, optical, and optoelectronic properties and thermal stability.

To achieve the above objective, one embodiment of the invention discloses a spirally configured cis-stilbene/fluorene hybrid material, which comprises a structure of the following General Formula (1).

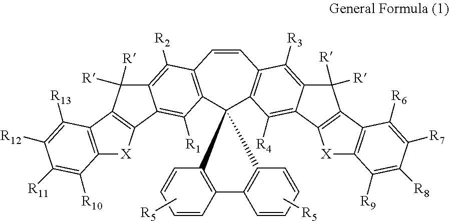

In the General formula (1), R′ is an alkyl group or represented by General Formula (2), X is represented by CR₃₆R₃₇ or NR₃₈, R₃₆ is represented by General Formula (3), R₃₇ is represented by General Formula (4), R₃₈ is represented by General Formula (5).

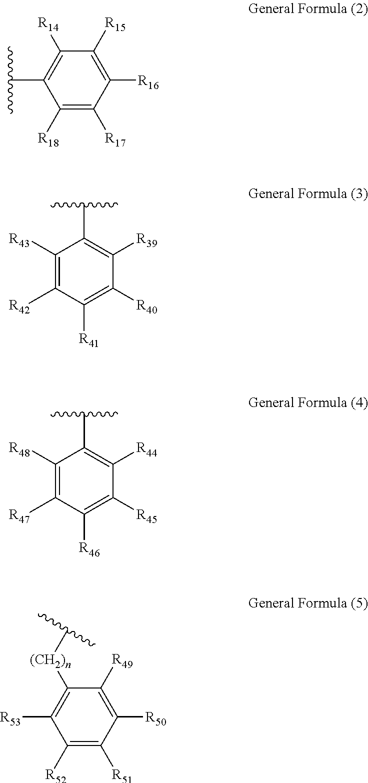

In the General formula (1), R₁ to R₄, R₆ to R₁₈ and R₃₉ to R₅₃ are each independently selected from the group consisting of a hydrogen atom, halogen atom, cyano group, alkyl group, cycloalkyl group, alkoxy group, amino group, haloalkyl group, thioalkyl group, silyl group and alkenyl group. R₅ is a hydrogen atom, tert-butyl group or naphthyl group, n is 0 or 1.

To achieve the above objective, an organic electroluminescent device is also disclosed. The organic electroluminescent comprises a first electrode layer, a second electrode layer, and an organic luminescent unit. The organic luminescent unit is deposited between the first electrode layer and the second electrode layer. The organic luminescent unit has at least a spirally configured cis-stilbene/fluorene hybrid material as shown in General Formula (1).

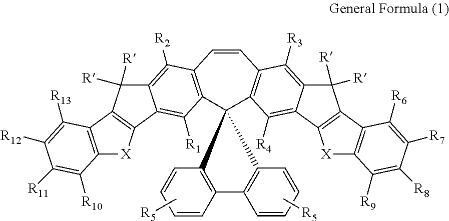

In the General formula (1), R′ is an alkyl group or represented by General Formula (2), X is represented by CR₃₆R₃₇ or NR₃₈, R₃₆ is represented by General Formula (3), R₃₇ is represented by General Formula (4), R₃₈ is represented by General Formula (5).

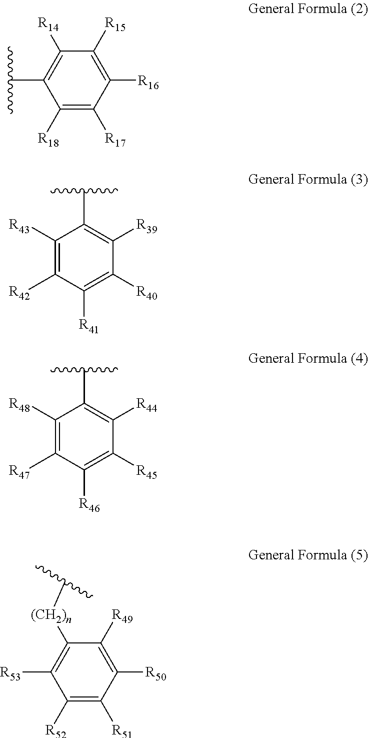

In the General formula (1), R₁ to R₄, R₆ to R₁₈ and R₃₉ to R₅₃ are each independently selected from the group consisting of a hydrogen atom, halogen atom, cyano group, alkyl group, cycloalkyl group, alkoxy group, amino group, haloalkyl group, thioalkyl group, silyl group and alkenyl group. R₅ is a hydrogen atom, tert-butyl group or naphthyl group, n is 0 or 1.

In one embodiment, the alkyl group is selected from the group consisting of a substituted or unsubstituted straight-chain alkyl group with the carbon number of 1 to 6, and a substituted or unsubstituted branched-chain alkyl group with the carbon number of 3 to 6, the cycloalkyl group is a substituted or unsubstituted cycloalkyl group with the carbon number of 3 to 6, the alkoxy group is selected from the group consisting of a substituted or unsubstituted straight-chain alkoxy group with the carbon number of 1 to 6, and a substituted or unsubstituted branched-chain alkoxy group with the carbon number of 3 to 6, the amino group is selected from the group consisting of secondary amino group and tertiary amino group, the secondary amino group is an amino group having one aromatic ring substituent or having one C1-C6 straight-chain alkyl, branch-chain alkyl, or non-aromatic ring, the tertiary amino group is an amino group having two independent aromatic ring substituents or having two independent C1-C6 straight-chain alkyl, branch-chain alkyl, or non-aromatic ring, the haloalkyl group is selected from the group consisting of a substituted or unsubstituted straight-chain haloalkyl group with the carbon number of 1 to 6, and a substituted or unsubstituted branched-chain haloalkyl group with the carbon number of 3 to 6, the thioalkyl group is selected from the group consisting of a substituted or unsubstituted straight-chain thioalkyl group with the carbon number of 1 to 6, and a substituted or unsubstituted branched-chain thioalkyl group with the carbon number of 3 to 6, the silyl group is selected from the group consisting of a substituted or unsubstituted straight-chain silyl group with the carbon number of 1 to 6, and a substituted or unsubstituted branched-chain silyl group with the carbon number of 3 to 6, the alkenyl group is selected from the group consisting of a substituted or unsubstituted straight-chain alkenyl group with the carbon number of 2 to 6, and a substituted or unsubstituted branched-chain alkenyl group with the carbon number of 3 to 6.

In one embodiment, the spirally configured cis-stilbene/fluorene hybrid material is represented by following chemical formula (1) or chemical formula (2).

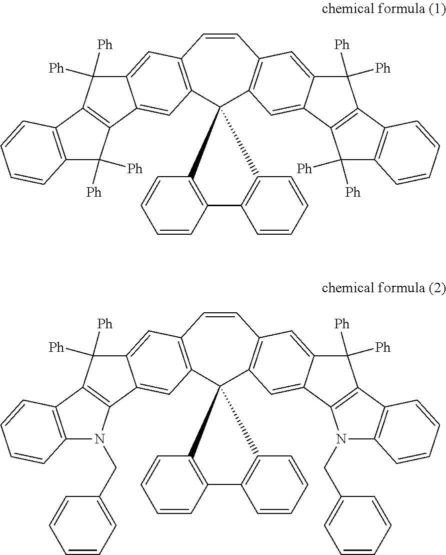

In one embodiment, the spirally configured cis-stilbene/fluorene hybrid material has glass transition temperatures ranged from 136° C. to 148° C.

In one embodiment, the spirally configured cis-stilbene/fluorene hybrid material has decomposition temperatures ranged from 414° C. to 475° C.

In one embodiment, the spirally configured cis-stilbene/fluorene hybrid material has oxidation potentials ranged from 0.63V to 0.72V and reduction potentials ranged from −2.04V to −2.22V.

In one embodiment, the spirally configured cis-stilbene/fluorene hybrid material has highest occupied molecular orbital energy level (E_{HOMO}) ranged from −5.43 eV to −5.52 eV and lowest unoccupied molecular orbital energy level (E_{LUMO}) ranged from −2.57 eV to −2.76 eV.

In one embodiment, the organic luminescent unit comprises an organic luminescent layer.

In one embodiment, the organic luminescent unit further comprises a hole transport layer and an electron transport layer, and the organic luminescent layer is deposited between the hole transport layer and the electron transport layer.

In one embodiment, the organic luminescent unit further comprises a hole injection layer, a hole transport layer, an electron transport layer and an electron injection layer, and the hole transport layer, the organic luminescent layer and the electron transport layer are sequentially deposited between the hole injection layer and the electron injection layer.

In one embodiment, the organic luminescent layer comprises the spirally configured cis-stilbene/fluorene hybrid material.

In one embodiment, the organic luminescent layer comprises a host material and a guest material, and the guest material comprises the spirally configured cis-stilbene/fluorene hybrid material.

In one embodiment, the content of the guest material in the organic luminescent layer is between 3 wt % to 15 wt %.

As mentioned above, in the spirally configured cis-stilbene/fluorene hybrid material and the organic electroluminescent device by using the same according to the present invention, two indenes or two pyrroles are fused with the spirally configured cis-stilbene/fluorene hybrid system, which acts as the core template. Herein, cis-stilbene with high geometric rigidity has high conjugation and fluorescence efficiency. When appended with the spiro fluorene group, the thermal stability of the whole material can be further increased. Also, due to such molecular configuration, intermolecular stacking does not occur easily so that fluorescence quenching effect caused by π-π stacking of the light emitting template can be prevented. In addition, both diindeno-fused molecular and dipyrrole-fused molecular possess high electron and hole transport properties and can improve the solubility in the solvent as well as the film forming ability. The most important is fluorescence property of the film is excellent. Therefore, the organic material of the present invention has excellent electronic, optical, and optoelectronic properties and thermal stability.

### BRIEF DESCRIPTION OF THE DRAWINGS

The embodiments will become more fully understood from the detailed description and accompanying drawings, which are given for illustration only, and thus are not limitative of the present invention, and wherein:

FIG. 1 is a cross-sectional schematic diagram of an organic electroluminescent device of the second embodiment according to the invention;

FIG. 2 is a cross-sectional schematic diagram of an organic electroluminescent device of the third embodiment according to the invention; and

FIG. 3 is a cross-sectional schematic diagram of an organic electroluminescent device of the fourth embodiment according to the invention.

### DETAILED DESCRIPTION OF THE INVENTION

The embodiments of the invention will be apparent from the following detailed description, which proceeds with reference to the accompanying drawings, wherein the same references relate to the same elements.

Spirally Configured Cis-Stilbene/Fluorene Hybrid Material

A spirally configured cis-stilbene/fluorene hybrid material according to the first embodiment of the present invention has a structure of the following General Formula (1).

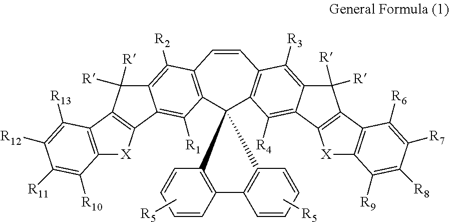

R′ is an alkyl group or represented by General Formula (2), X is represented by CR₃₆R₃₇ or NR₃₈, R₃₆ is represented by General Formula (3), R₃₇ is represented by General Formula (4), R₃₈ is represented by General Formula (5).

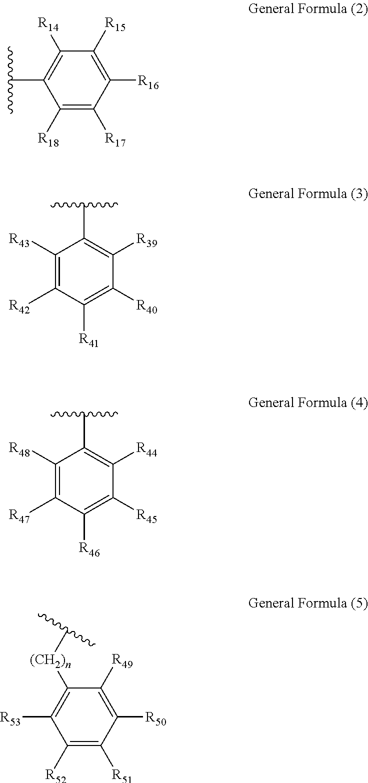

R₁ to R₄, R₆ to R₁₈ and R₃₉ to R₅₃ are each independently selected from the group consisting of a hydrogen atom, halogen atom, cyano group, alkyl group, cycloalkyl group, alkoxy group, amino group, haloalkyl group, thioalkyl group, silyl group and alkenyl group. R₅ is a hydrogen atom, tert-butyl group or naphthyl group. n is 0 or 1.

In the present embodiment, the alkyl group can be selected from the group consisting of a substituted or unsubstituted straight-chain alkyl group with the carbon number of 1 to 6, and a substituted or unsubstituted branched-chain alkyl group with the carbon number of 3 to 6. The cycloalkyl group can be a substituted or unsubstituted cycloalkyl group with the carbon number of 3 to 6. The alkoxy group can be selected from the group consisting of a substituted or unsubstituted straight-chain alkoxy group with the carbon number of 1 to 6, and a substituted or unsubstituted branched-chain alkoxy group with the carbon number of 3 to 6. The amino group can be selected from the group consisting of secondary amino group and tertiary amino group. The haloalkyl group can be selected from the group consisting of a substituted or unsubstituted straight-chain haloalkyl group with the carbon number of 1 to 6, and a substituted or unsubstituted branched-chain haloalkyl group with the carbon number of 3 to 6. The thioalkyl group can be selected from the group consisting of a substituted or unsubstituted straight-chain thioalkyl group with the carbon number of 1 to 6, and a substituted or unsubstituted branched-chain thioalkyl group with the carbon number of 3 to 6. The silyl group can be selected from the group consisting of a substituted or unsubstituted straight-chain silyl group with the carbon number of 1 to 6, and a substituted or unsubstituted branched-chain silyl group with the carbon number of 3 to 6. The alkenyl group can be selected from the group consisting of a substituted or unsubstituted straight-chain alkenyl group with the carbon number of 2 to 6, and a substituted or unsubstituted branched-chain alkenyl group with the carbon number of 3 to 6.

Moreover, the secondary amino group can be an amino group having one aromatic ring substituent (for example, a phenyl amino group) or having one C1-C6 straight-chain alkyl, branch-chain alkyl, or non-aromatic ring (for example, a methyl amino group). The tertiary amino group can be an amino group having two independent aromatic ring substituents (for example, a diphenyl amino group, —NPh₂) or having two independent C1-C6 straight-chain alkyl, branch-chain alkyl, or non-aromatic ring (for example, a dimethyl amino group).

The spirally configured cis-stilbene/fluorene hybrid material according to the present embodiment represented by General Formula (1) can be a material of an organic luminescent layer in an organic electroluminescent device, especially can be a guest material. A preferred example is the compound of chemical formula (1), INDCP-STIF, where R′ is represented by General Formula (2), X is represented by CR₃₆R₃₇, R₃₆ is represented by General Formula (3), R₃₇ is represented by General Formula (4), R₁ to R₁₈ and R₃₉ to R₄₈ are all independent hydrogen atoms.

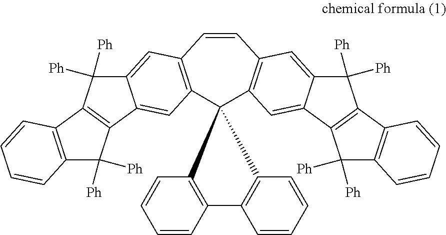

Alternatively, another preferred example is the compound of chemical formula (2), IDOCP-STIF, where R′ is represented by General Formula (2), X is represented by NR₃₈, R₃₈ is represented by General Formula (5), n is 1, R₁ to R₁₈ and R₄₉ to R₅₃ are all independent hydrogen atoms.

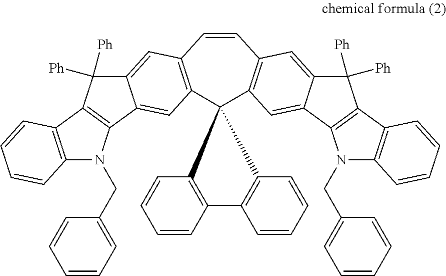

Moreover, in the present embodiment, the spirally configured cis-stilbene/fluorene hybrid materials have glass transition temperatures ranged from 136° C. to 148° C., decomposition temperatures ranged from 414° C. to 475° C., oxidation potentials ranged from 0.63V to 0.72V and reduction potentials ranged from −2.04V to −2.22V. In addition, the highest occupied molecular orbital energy levels (E_{HOMO}) of the spirally configured cis-stilbene/fluorene hybrid materials are ranged from −5.43 eV to −5.52 eV and their lowest unoccupied molecular orbital energy levels (E_{LUMO}) are ranged from −2.57 eV to −2.76 eV.

Organic Electroluminescent Device

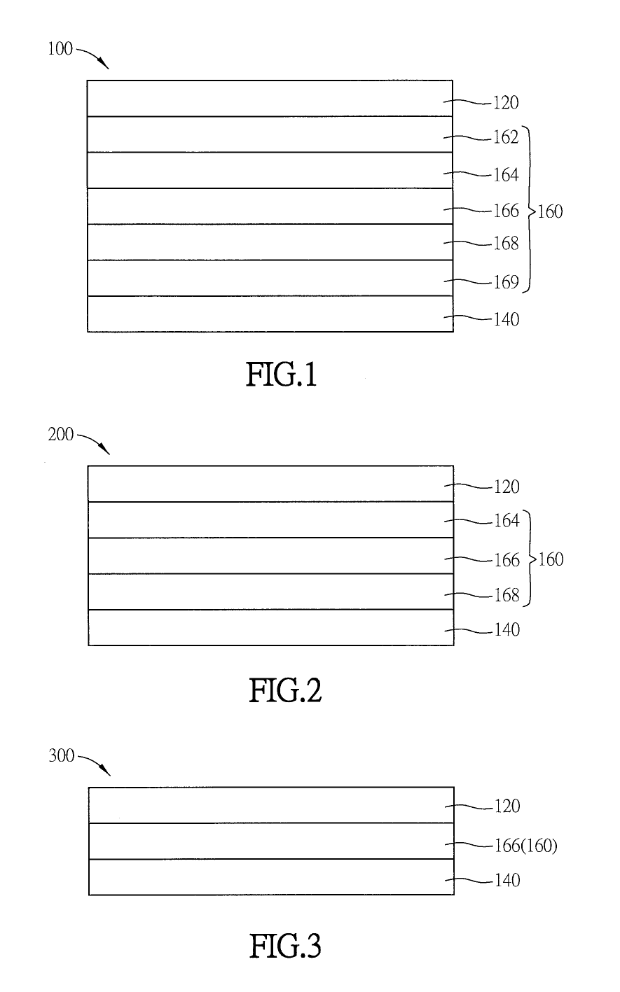

Please refer to FIG. 1, an organic electroluminescent device 100 of the second embodiment according to the invention includes a first electrode layer 120, a second electrode layer 140 and an organic luminescent unit 160. In the embodiment, the first electrode layer 120 can be a transparent electrode material, such as indium tin oxide (ITO), and the second electrode layer 140 can be a metal, transparent conductive substance or any other suitable conductive material. On the other hand, the first electrode layer 120 can also be a metal, transparent conductive substance or any other suitable conductive material, and the second electrode layer 140 can also be a transparent electrode material. Specifically, at least one of the first electrode layer 120 and the second electrode layer 140 of the present embodiment is a transparent electrode material, so that the light emitted from the organic luminescent unit 160 may pass through the transparent electrode, thereby enabling the organic electroluminescent device 100 to emit light.

In addition, please also refer to FIG. 1, the organic luminescent unit 160 can comprise a hole injection layer 162, a hole transport layer 164, an organic luminescent layer 166, an electron transport layer 168 and an electron injection layer 169. The hole transport layer 164, the organic luminescent layer 166 and the electron transport layer 168 are sequentially deposited between the hole injection layer 162 and the electron injection layer 169.

Herein, the materials of the hole injection layer 162 can be poly(3,4-ethylenedioxythiophene) polystyrene sulfonate (PEDOT:PSS). Moreover, the thickness of the hole injection layer 162 of the embodiment is, for example, less than 40 nm. The materials of the hole transport layer 164 can be 1,1-Bis[4-[N,N′-di(p-tolyflamino]phenyl]cyclohexane (TAPC), N,N-bis-(1-naphthyl)-N,N-diphenyl-1,1-biphenyl-4,4-diamine (NPB) or N—N′-diphenyl-N—N′bis(3-methylphenyl)-[1-1′-biphenyl]-4-4′-diamine (TPD) and so on. In the embodiment, the hole injection layer 162 and the hole transport layer 164 can increase the injection rate of hole transported from the first electrode layer 120 to the organic luminescent layer 166 and can also reduce the driving voltage of the organic electroluminescent device 100.

The materials of the electron transport layer 168 can be 2,2,2-(1,3,5-benzinetriyl)-tris(1-phenyl-l-H-benzimidazole) (TBPI) or 1,3-Bis[3,5-di(pyridin-3-yl)phenyl]benzene (BmPyPb). In the embodiment, the thickness of the electron transport layer 168 is, for example, less than 50 nm. In the present embodiment, the electron transport layer 168 may further increase the transport rate of the electron from the electron injection layer 169 to the organic luminescent layer 166.

In addition, the thickness of the organic luminescent layer 166 can be between 5 nm and 40 nm, for example, 32 nm. The organic luminescent layer 166 may include the host material and the guest material, and the doping concentration of the guest material (weight percentage) can be ranged from 1 wt % to 20 wt %. More specifically, the content of the guest material in the organic luminescent layer 166 can be ranged from 3 wt % to 10 wt % or from 5 wt % to 15 wt %, for example, 3 or 15 wt %.

The host materials can be 4,4′-Bis(N-carbazolyl)-1,1′-biphenyl (CBP), N,N′-Di(1-naphthyl)-N,N′-diphenyl-(1,1′-biphenyl)-4,4′-diamine (NBP), 3,5-di(9H-carbazol-9-yl)tetraphenylsilane (SimCP2), 4,4′,4″-tri(N-carbazolyl)triphenylamine (TCTA), 2,7-bis(carbazo-9-yl)-9,9-ditolyfluorene (Spiro-2CBP) or the host materials with 9, 10-diaryl substituents, for example, 10,10′-di(biphenyl-4-yl)-9,9′-bianthracene (BANE).

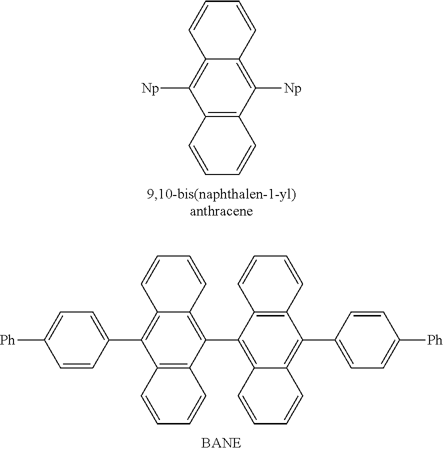

Herein, the guest material can be the spirally configured cis-stilbene/fluorene hybrid material which has a structure of General Formula (1).

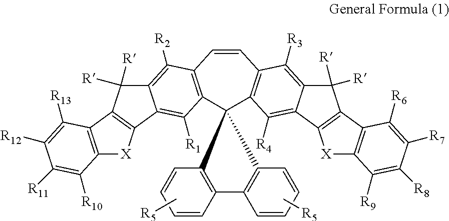

R′ is an alkyl group or represented by General Formula (2), X is represented by CR₃₆R₃₇ or NR₃₈, R₃₆ is represented by General Formula (3), R₃₇ is represented by General Formula (4), R₃₈ is represented by General Formula (5).

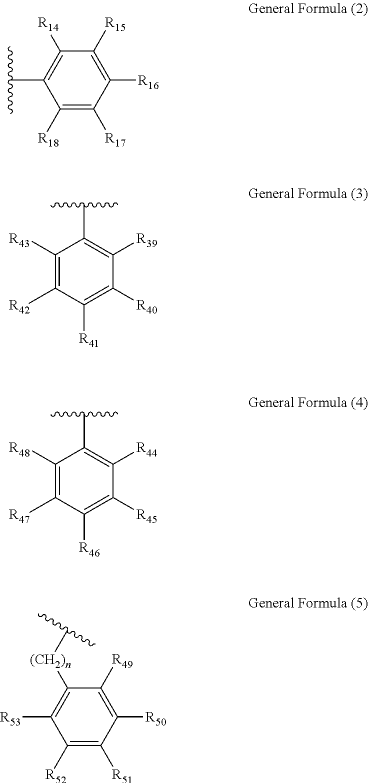

R₁ to R₄, R₆ to R₁₈ and R₃₉ to R₅₃ are each independently selected from the group consisting of a hydrogen atom, halogen atom, cyano group, alkyl group, cycloalkyl group, alkoxy group, amino group, haloalkyl group, thioalkyl group, silyl group and alkenyl group. R₅ is a hydrogen atom, tert-butyl group or naphthyl group. n is 0 or 1.

In addition, FIG. 2 is a cross-sectional schematic diagram of an organic electroluminescent device 200 of the third embodiment according to the invention. The configuration of the organic electroluminescent device 200 is substantially similar with that of the organic electroluminescent device 100, and same elements have substantial the same characteristics and functions. Therefore, the similar references relate to the similar elements, and detailed explanation is omitted hereinafter.

Please refer to FIG. 2, in the embodiment, the organic luminescent unit 160 can comprise a hole transport layer 164, an organic luminescent layer 166 and an electron transport layer 168. The organic luminescent layer 166 is deposited between the hole transport layer 164 and the electron transport layer 168.

In addition, FIG. 3 is a cross-sectional schematic diagram of an organic electroluminescent device 300 of the fourth embodiment according to the invention. The configuration of the organic electroluminescent device 300 is substantially similar with that of the organic electroluminescent device 100, and same elements have substantial the same characteristics and functions. Therefore, the similar references relate to the similar elements, and detailed explanation is omitted hereinafter.

Please refer to FIG. 3, in the embodiment, the organic luminescent unit 160 can comprise an organic luminescent layer 166.

Moreover, the configuration of the organic electroluminescent device according to the invention is not limited to what is disclosed in the second, third or fourth embodiment. The second, third and fourth embodiments are embodiments for illustration.

In addition, the various examples, the selection of the substituents of R′, R₁ to R₁₈ and R₃₉ to R₅₃ and the number of n in General Formula (1) of the spirally configured cis-stilbene/fluorene hybrid materials in the second, third and fourth embodiments, as well as their properties, such as glass transition temperatures, decomposition temperatures, oxidation potentials, redox potentials, the highest occupied molecular orbital energy levels and the lowest unoccupied molecular orbital energy levels, are substantially the same as those in the first embodiment and are therefore omitted here.

To illustrate the synthesis of the compounds represented by chemical formula (1) and chemical formula (2), there are several examples shown below.

The synthetic process of 2,3,7,8-{11,16-Dihydro-11,11,16,16-tetraphenyl-indeno[1,2-a]indenyl}-5,5-spirofluorenyl-5H-dibenzo-[a,d]cycloheptene (chemical formula (1): INDCP-STIF, compound 16a):

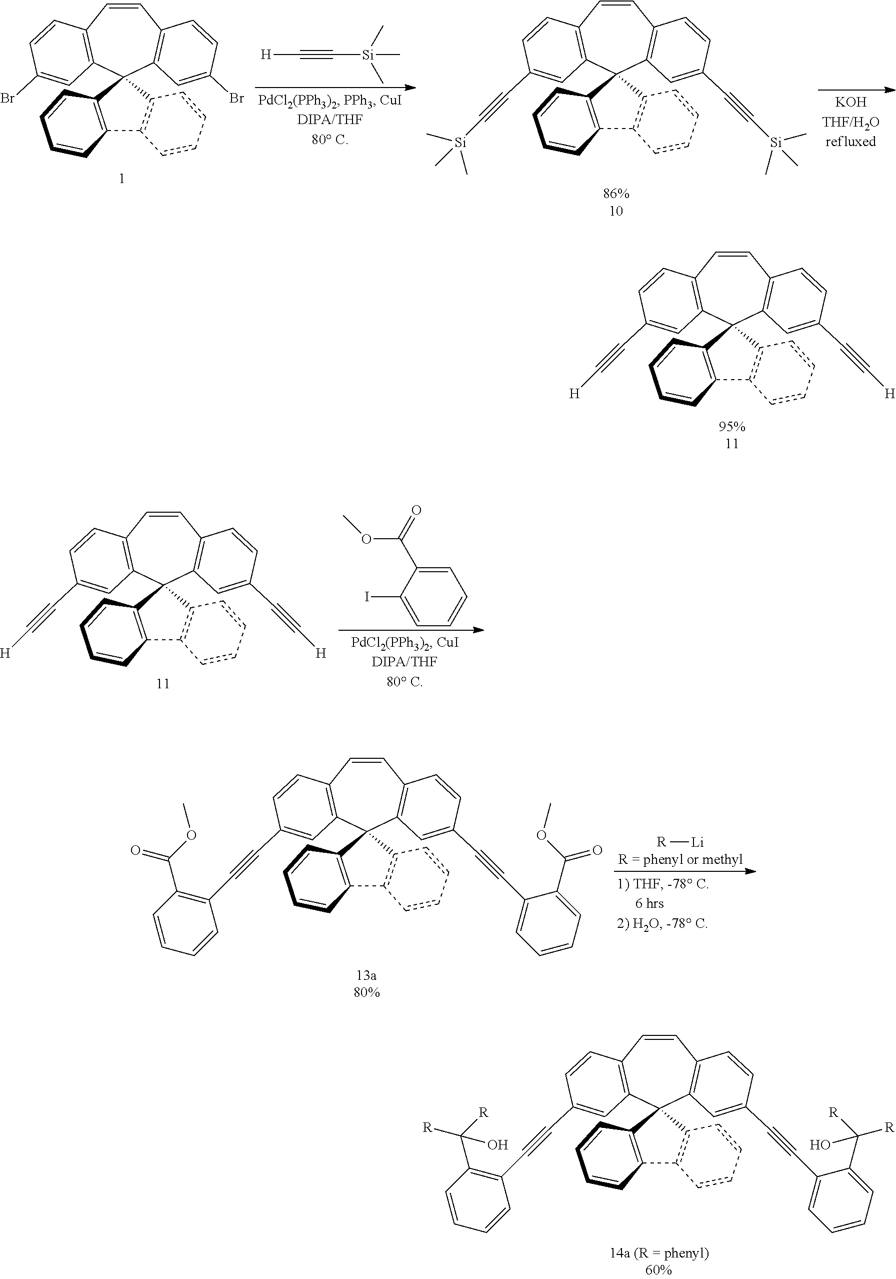

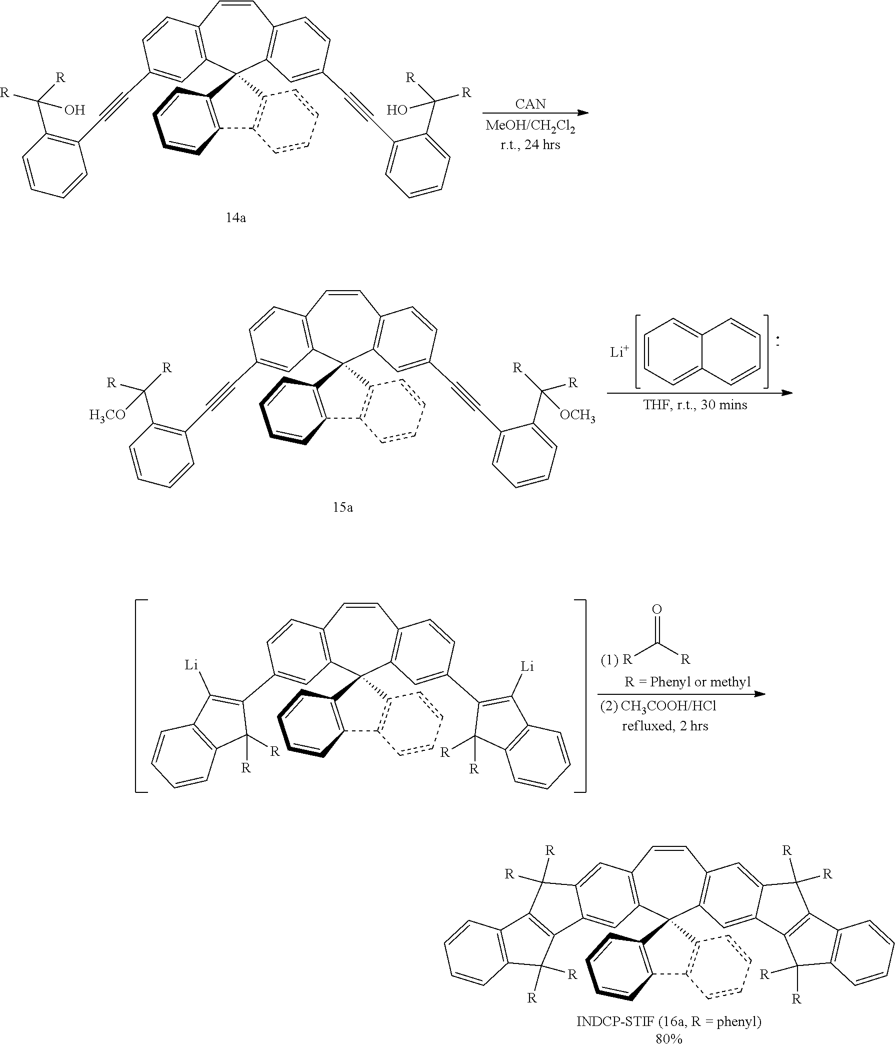

### Example 1: Synthesis of Compound 10 (3,7-Bis(trimethylsilylacetylenyl)-5,5-spirofluorenyl-5H-dibenzo-[a,d]cycloheptene)

A 25 mL two-necked, round-bottomed flask placed with a stir bar was equipped to a reflux condenser system and then dried by vacuum followed by back-filling with nitrogen gas. Compound 1 (500 mg, 1 mmol), triphenylphosphine (16 mg, 6 mol %), copper(I) iodide (11 mg, 6 mol %) and catalyst Pd(PPh₃)₂Cl₂ (20 mg, 3 mol %) were added to the flask, followed by the addition of deoxygenated diisopropylamine (2 mL) and deoxygenated tetrahydrofuran (3 mL). After reacting for 10 minutes at 80° C., trimethylsilylacetylene (0.4 mL, 3 mmol) was added drop by drop to the flask. After further reacting for 8 hours at 80° C., the flask was cooled down to room temperature and then removed from the reflux condenser system. Saturated aqueous ammonium chloride solution (20 mL) was then added to quench the reaction. The solvent was removed by rotator evaporation and the reaction mixture was then extracted by dichloromethane (3×20 ml). The combined extractant was then dried by adding anhydrous magnesium sulfate, followed by filtration and condensation with a rotary evaporator to obtain a crude product. The crude product was then purified by column chromatography using a mixture of dichloromethane and hexanes (1/3) as eluent and crude compound 10 was obtained. Followed by recrystallized from dichloromethane/hexanes, pure compound 10 (460 mg, yield: 86%) was obtained. Spectral data as follow: mp: 277-278° C.; M.W. 534.84; ¹H NMR (400 MHz, CDCl₃) δ 7.89 (d, J=7.6, 2H), 7.75 (d, J=7.6, 2H), 7.38 (t, J=7.6, 2H), 7.29-7.24 (m, 6H), 6.94 (s, 2H), 6.92 (s, 2H), 0.14 (s, 18H); ¹³C NMR (100 MHz, CDCl₃) δ 151.9, 141.7, 138.9, 136.5, 133.3, 132.5, 132.2, 130.7, 128.1, 127.6, 126.8, 123.0, 120.4, 105.1, 95.4, 65.5, −0.1; TLC R_{f} 0.72 (CH₂Cl₂/hexanes, 1/3); HR-MS calcd for C₃₇H₃₄Si₂: 534.2199, found: 534.2191; IR (KBr) v 3064 (w), 3034 (w), 2958 (m), 2898 (w), 2152 (m), 1638 (br), 1593 (w), 1537 (w), 1495 (m), 1446 (m), 1407 (w), 1381 (w), 1328 (w), 1296 (w), 1249 (m), 1214 (w), 1152 (w), 1113 (w), 1089 (br), 1007 (w).

### Example 2: Synthesis of Compound 11 (3,7-Dienthylenyl-5,5-spirofluorenyl-5H-dibenzo-[a,d]cycloheptene)

A 50 mL single-necked, round-bottomed flask placed with a stir bar was equipped to a reflux condenser system. After filled with nitrogen gas, compound 10 (535 mg, 1 mmol) and potassium hydroxide (112 mg, 2 mmol) were added to the flask. After adding tetrahydrofuran (10 mL) and deionized water (5 mL), the mixture was refluxed for 5 hours. The flask was cooled down to room temperature and then removed from the reflux condenser system. Saturated aqueous ammonium chloride solution (20 mL) was then added to quench the reaction. The solvent was removed by rotator evaporation and the reaction mixture was then extracted by dichloromethane (3×20 ml). The combined extractant was then dried by adding anhydrous magnesium sulfate, followed by filtration and condensation with a rotary evaporator to obtain a crude product. The crude product was then purified by recrystallized from dichloromethane/hexanes, compound 11 (371 mg, yield: 95%) was obtained. Spectral data as follow: mp: 294-296° C.; M.W. 390.47; ¹H NMR (400 MHz, CDCl₃) δ 7.89 (d, J=7.6, 2H), 7.74 (d, J=7.6, 2H), 7.38 (t, J=7.6, 2H), 7.28-7.23 (m, 6H), 6.99 (s, 2H), 6.93 (s, 2H), 2.93 (s, 2H); ¹³C NMR (100 MHz, CDCl₃) δ 151.8, 141.8, 141.7, 138.9, 138.8, 136.7, 133.4, 133.4, 132.7, 132.2, 130.8, 128.3, 127.7, 126.7, 122.0, 120.4, 83.5, 78.1, 65.5; TLC R_{f} 0.65 (CH₂Cl₂/hexanes, 1/3); HR-MS calcd for C₃₁H₁₈: 390.1409, found: 390.1419; IR (KBr) v 3289 (s), 3059 (w), 3033 (w), 2928 (w), 2104 (w), 1594 (w), 1560 (w), 1535 (w), 1494 (s), 1473 (w), 1445 (s), 1381 (m), 1353 (br), 1263 (w), 1208 (br), 1134 (w), 1122 (w), 1105 (w), 1090 (w), 1006 (w).

### Example 3: Synthesis of Compound 13a (3,7-Bis(2-methylbenzoylethylenyl)-5,5-spirofluorenyl-5H-dibenzo-[a,d]cycloheptene)

A 25 mL, two-necked, round-bottomed flask placed with a stir bar was dried by vacuum followed by back-filling with nitrogen gas. Compound 11 (391 mg, 1 mmol), methyl 2-iodobenzoate (0.3 mL, 2.1 mmol), copper(I) iodide (11 mg, 6 mol %), catalyst Pd(PPh₃)₂Cl₂ (20 mg, 3 mol %), deoxygenated diisopropylamine (2 mL) and deoxygenated tetrahydrofuran (3 mL) were added to the flask. After reacting for 4 hours at room temperature, saturated aqueous ammonium chloride solution (20 mL) was added to quench the reaction. The solvent was removed by rotator evaporation and the reaction mixture was then extracted by dichloromethane (3×20 ml). The combined extractant was then dried by adding anhydrous magnesium sulfate, followed by filtration and condensation with a rotary evaporator to obtain a crude product. The crude product was then purified by column chromatography using a mixture of dichloromethane and hexanes (2/1) as eluent and crude compound 13a was obtained. Followed by recrystallized from dichloromethane/hexanes, compound 13a (526 mg, yield: 80%) was obtained. Spectral data as follow: mp: 265-268° C.; M.W. 658.74; ¹H NMR (400 MHz, CDCl₃) δ 7.96 (d, J=7.6, 2H), 7.90 (dd, J=6.8, 1.2, 2H), 7.76 (d, J=7.2, 2H), 7.48 (dd, J=6.8, 1.2, 2H), 7.42-7.26 (m, 12H), 7.07 (d, J=1.2, 2H), 6.96 (s, 2H), 3.75 (s, 6H); ¹³C NMR (100 MHz, CDCl₃) δ 152.3, 141.8, 138.9, 136.6, 133.8, 133.4, 132.5, 132.2, 131.9, 131.5, 130.6, 130.4, 128.4, 128.3, 127.9, 126.9, 126.8, 123.3, 120.4, 94.3, 89.4, 65.7, 52.1; TLC R_{f} 0.30 (CH₂Cl₂/hexanes, 2/1); HR-MS calcd for C₄₇H₃₀O₄: 658.2144, found: 658.2150; IR (KBr) v 3060 (w), 3031 (w), 2948 (w), 2209 (w), 1727 (s), 1717 (s), 1596 (w), 1565 (w), 1498 (m), 1479 (m), 1446 (m), 1432 (w), 1382 (w), 1352 (w), 1292 (s), 1267 (w), 1253 (w), 1191 (w), 1128 (m), 1078 (s), 1042 (w), 1006 (w).

### Example 4: Synthesis of Compound 14a (3,7-Bis(2-diphenylhydroxyethylenyl)-5,5-spirofluorenyl-5H-dibenzo-[a,d]cycloheptene)

A 50 mL, two-necked, round-bottomed flask placed with a stir bar was dried by vacuum followed by back-filling with nitrogen gas. A 1.6 M solution of phenyllithium in diethyl ether (3 mL, 5 mmol) or methyllithium in n-hexane (5 mmol) was added drop by drop to the flask placed with a solution of compound 13a (659 mg, 1 mmol) in anhydrous tetrahydrofuran (4 mL) at −78° C. After reacting for 6 hours at −78° C., deionized water (20 ml) was added to quench the reaction, followed by return to room temperature from −78° C. At room temperature, the solvent was removed by rotator evaporation and the reaction mixture was then extracted by dichloromethane (3×20 ml). The combined extractant was then dried by adding anhydrous magnesium sulfate, followed by filtration and condensation with a rotary evaporator to obtain a crude product. The crude product was then purified by column chromatography using a mixture of dichloromethane and hexanes (1/2) as eluent and crude compound 14a was obtained. Followed by recrystallized from dichloromethane/hexanes, compound 14a (680 mg, yield: 75%) was obtained. Spectral data as follow: mp: 218-220° C.; M.W. 907.10; ¹H NMR (400 MHz, CDCl₃) δ 7.89 (d, J=7.6, 2H), 7.83 (d, J=7.2, 2H), 7.47-7.43 (m, 4H), 7.33 (t, J=6.8, 2H), 7.27-7.20 (m, 24H), 7.15 (t, J=6.4, 2H), 6.91 (s, 2H), 6.86 (d, J=1.6, 2H), 6.79 (dd, J=6.4, 1.2, 2H), 6.67 (dd, J=7.2, 0.8, 2H), 4.65 (s, 2H); ¹³C NMR (100 MHz, CDCl₃) δ 151.8, 149.3, 146.1, 141.7, 138.9, 136.6, 134.1, 133.4, 132.2, 131.5, 130.2, 129.2, 128.5, 127.9, 127.7, 127.2, 127.1, 126.8, 122.2, 121.3, 120.5, 97.2, 89.5, 82.4, 65.5; TLC R_{f} 0.38 (CH₂Cl₂/hexanes, 1/2); HR-MS calcd for C₆₉H₄₆O₂: 906.3498, found: 906.3489; IR (KBr) v 3497 (br), 3058 (w), 3026 (w), 2922 (w), 2855 (w), 1663 (br), 1654 (br), 1648 (br), 1629 (br), 1596 (w), 1492 (m), 1474 (w), 1446 (s), 1383 (w), 1347 (br), 1265 (w), 1202 (w), 1159 (w), 1079 (w), 1049 (w), 1031 (w), 1015 (m).

### Example 5: Synthesis of Compound 15a (3,7-Bis(2-diphenylmethoxyethylenyl)-5,5-spirofluorenyl-5H-dibenzo-[a,d]cycloheptene)

A 25 mL, two-necked, round-bottom flask placed with a stir bar was dried by vacuum followed by back-filling with nitrogen gas. Compound 14a (454 mg, 0.5 mmol), methanol (6 mL) and dichloromethane (6 mL) were added to the flask, followed by the addition of ceric ammonium nitrate (CAN, 110 mg, 40 mol %). After reacting for 24 hours at room temperature, the solvent was removed by rotator evaporation and the reaction mixture was then purified by column chromatography using a mixture of dichloromethane and hexanes (1/3) as eluent and crude compound 15a was obtained. Followed by recrystallized from dichloromethane/hexanes, compound 15a (327 mg, yield: 70%) was obtained. Spectral data as follow: mp: 177-180° C.; M.W. 935.16; ¹H NMR (400 MHz, CDCl₃) δ 7.94 (d, J=7.2, 2H), 7.80 (d, J=7.2, 2H), 7.44-7.39 (m, 10H), 7.36 (dd, J=6.4, 1.2, 2H), 7.32-7.27 (m, 4H), 7.24-7.10 (m, 18H), 6.91 (s, 2H), 6.86 (d, J=1.6, 2H), 6.74 (dd, J=6.4, 2.6, 2H), 2.99 (s, 6H); ¹³C NMR (100 MHz, CDCl₃) δ 152.1, 145.6, 142.3, 141.4, 138.9, 136.1, 134.8, 133.2, 132.1, 132.1, 131.5, 130.2, 128.8, 128.4, 128.2, 127.9, 127.8, 127.7, 127.4, 127.0, 126.8, 123.5, 122.5, 120.4, 120.3, 96.1, 91.4, 65.6, 52.1; TLC R_{f} 0.36 (CH₂Cl₂/hexanes, 1/3); HR-MS calcd for C₇₁H₅₀O₂: 934.3811, found: 934.3826; IR (KBr) v 3057 (w), 3031 (w), 2933 (w), 2824 (w), 1594 (w), 1491 (m), 1474 (w), 1446 (s), 1381 (br), 1356 (br), 1264 (w), 1216 (br), 1155 (w), 1072 (s), 1015 (w), 1002 (w).

### Example 6: Synthesis of Compound 16a (Chemical Formula (1): INDCP-STIF; (2,3,7,8-{11,16-Dihydro-11,11,16,16-tetraphenyl-indeno[1,2-a]indenyl}-5,5-spirofluorenyl-5H-di benzo-[a,d]cycloheptene)

A 25 mL high pressure test tube placed with a stir bar was dried by vacuum followed by back-filling with nitrogen gas. Granular lithium metal (10 mg, 1.5 mmol), naphthalene (154 mg, 1.2 mmol) and anhydrous tetrahydrofuran (2 mL) were added to the test tube. After reacting for 5 hours at room temperature, Li-naphthalene complex solution was obtained. Another 25 mL high pressure test tube placed with a stir bar was dried by vacuum followed by back-filling with nitrogen gas. Compound 15a (281 mg, 0.3 mmol) and anhydrous tetrahydrofuran (4 mL) were added to the another test tube, followed by injecting the above Li-naphthalene complex solution into the test tube with compound 15a by using a gas tight syringe at room temperature. After reacting for 30 minutes at room temperature, benzophenone (109 mg, 0.6 mmol) or anhydrous acetone (0.6 mmol) was added to the test tube and then react for 3 hours at room temperature. Saturated aqueous sodium bicarbonate solution (10 mL) was added to quench the reaction. The tetrahydrofuran was removed by rotator evaporation and the reaction mixture was then extracted by dichloromethane (3×20 ml). The combined extractant was then dried by adding anhydrous magnesium sulfate, followed by filtration and condensation with a rotary evaporator to obtain a crude product. 10 mL of acetic acid (10 mL) and catalyst hydrochloric acid (12 N, 5 mol %) were added to the crude product, and the reaction mixture was refluxed for 2 hours. After cooling down to room temperature, saturated aqueous sodium bicarbonate solution (20 mL) was added to quench the reaction. The acetic acid was removed by rotator evaporation and the reaction mixture was then extracted by dichloromethane (3×20 ml). The combined extractant was then dried by adding anhydrous magnesium sulfate, followed by filtration and condensation with a rotary evaporator to obtain a crude product. The crude product was then purified by column chromatography using a mixture of dichloromethane and hexanes (1/3) as eluent and crude compound 16a was obtained. Followed by recrystallized from dichloromethane/hexanes, compound 16a (Chemical formula (1), 288 mg, yield: 80%) was obtained. Spectral data as follow: mp: 263° C. (DSC); M.W. 1203.51; ¹H NMR (400 MHz, CDCl₃) δ 8.12 (d, J=7.6, 2H), 7.85 (d, J=7.6, 2H), 7.50 (t, J=7.2, 2H), 7.38 (s, 4H), 7.37-7.33 (m, 6H), 7.27-7.26 (m, 8H), 7.23-7.19 (m, 36H), 6.91 (s, 2H); ¹³C NMR (100 MHz, CDCl₃) δ 151.2, 143.2, 142.7, 142.5, 141.6, 138.7, 134.2, 133.1, 132.1, 131.7, 131.0, 130.9, 128.5, 128.4, 128.2, 128.0, 127.8, 127.6, 127.5, 127.3, 127.2, 127.0, 126.8, 126.7, 126.6, 126.3, 126.1, 125.6, 125.1, 124.8, 124.1, 121.2, 120.8, 120.7, 119.6, 65.8; Anal. Calcd for C₉₅H₆₂ (MW: 1203.51): C, 94.81; H, 5.19. Found: C, 94.47; H, 5.48; TLC R_{f} 0.33 (CH₂Cl₂/hexanes, 1/3); HR-MS calcd for C₉₅H₆₂: 1202.4852, found: 1202.4867; IR (KBr) v 3057 (w), 3022 (w), 2923 (w), 2851 (w), 1686 (br), 1678 (br), 1596 (m), 1491 (m), 1445 (m), 1352 (m), 1211 (w), 1121 (br), 1103 (br), 1080 (br), 1001 (w).

### Example 7: Synthesis of Compound 12 (Benzyl(2-iodophenyl)amine)

A 50 mL, two-necked, round-bottomed, flask placed with a stir bar was equipped to a reflux condenser system, and then dried by vacuum followed by back-filling with nitrogen gas. 2-iodoaniline (4380 mg, 20 mmol), benzaldehyde (3 mL, 24 mmol) and zinc chloride (3271 mg, 24 mmol) were added to the flask under a nitrogen gas system and then dissolved in methanol (100 mL). Then NaCNBH₃ (1568 mg, 24 mmol) was added to the flask, and the reaction mixture was refluxed for 2 hours. The flask was cooled down to room temperature and then removed from the reflux condenser system. Saturated aqueous sodium bicarbonate solution (20 mL) was added to quench the reaction. The solvent was removed by rotator evaporation and the reaction mixture was then extracted by dichloromethane (3×20 ml). The combined extractant was then dried by adding anhydrous magnesium sulfate, followed by filtration and condensation with a rotary evaporator to obtain a crude product. The crude product was purified by column chromatography using a mixture of ethyl acetate/hexanes (1/10) as eluent and compound 12 (5540 mg, yield: 88%) was obtained. Spectral data as follow: M.W. 309.15; ¹H NMR (400 MHz, CDCl₃) δ 7.80 (dd, J=6.4, 1.2, 1H), 7.47 (d, J=8.8, 4H), 7.39-7.37 (m, 1H), 7.27-7.23 (m, 1H), 6.64 (dd, J=6.8, 1.2, 1H), 6.57 (td, J=6.0, 1.6, 1H), 4.74 (s, 1H), 4.48 (s, 2H); ¹³C NMR (100 MHz, CDCl₃) δ 146.9, 138.8, 138.5, 129.3, 128.8, 128.6, 128.1, 127.2, 127.1, 118.7, 110.9, 85.3, 48.2; TLC R_{f} 0.80 (hexanes); HR-MS calcd for C₁₃H₁₂IN: 309.0014, found: 309.0012; IR (KBr) v 3401 (s), 3061 (s), 3028 (s), 2923 (m), 2854 (m), 1949 (br), 1883 (br), 1807 (br), 1702 (w), 1590 (s), 1505 (s), 1469 (m), 1450 (s), 1425 (m), 1360 (m), 1319 (s), 1295 (s), 1234 (m), 1162 (m), 1126 (m), 1067 (m), 1027 (w), 1004 (s).

The Synthetic process of 2,3,7,8-{N-Benzyl-12,17-dihydro-17,17-diphenyl-Indeno [1,2-a]indenyl}-5,5-spirofluorenyl-5H-dibenzo[a,d]cycloheptene (Chemical formula (2): IDOCP-STIF, compound 16b):

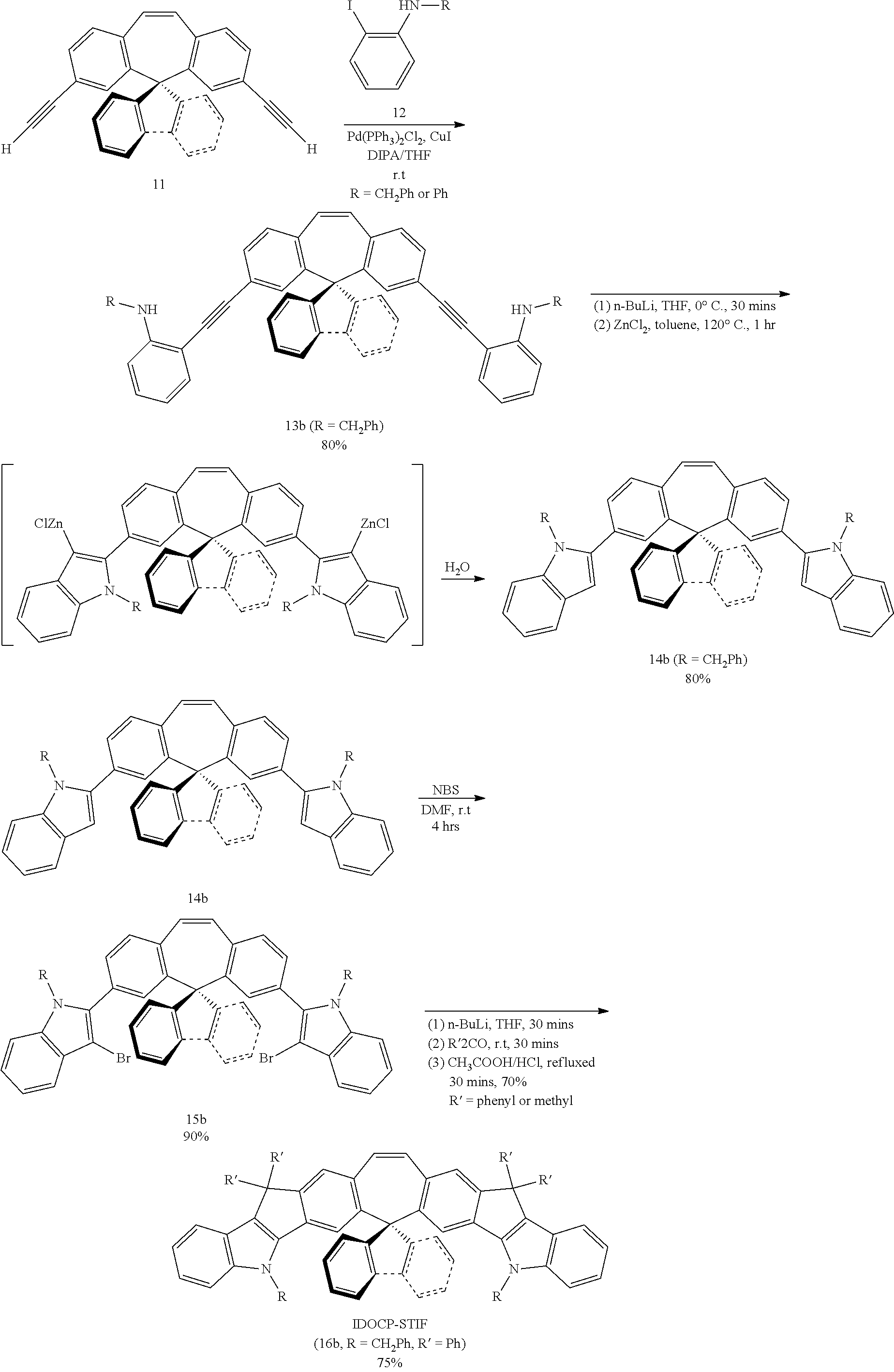

### Example 8: Synthesis of Compound 13b (3,7-Bis(N-benzyl-2-phenylethylnyl)-5,5-spirofluorenyl-5H-dibenzo-[a,d]cycloheptene)

A 25 mL, two-necked, round-bottomed, flask placed with a stir bar was dried by vacuum followed by back-filling with nitrogen gas. Compound 11 (391 mg, 1 mmol), compound 12 (649 mg, 2.1 mmol), copper(I) iodide (11 mg, 6 mol %) and catalyst Pd(PPh₃)₂Cl₂ (20 mg, 3 mol %) were added to the flask, followed by the addition of deoxygenated diisopropylamine (2 mL) and deoxygenated tetrahydrofuran (3 mL). After reacting for 4 hours at room temperature, saturated aqueous ammonium chloride solution (20 mL) was then added to quench the reaction. The solvent was removed by rotator evaporation and the reaction mixture was then extracted by dichloromethane (3×20 ml). The combined extractant was then dried by adding anhydrous magnesium sulfate, followed by filtration and condensation with a rotary evaporator to obtain a crude product. The crude product was then purified by column chromatography using a mixture of dichloromethane and hexanes (1/3) as eluent and crude compound 13b was obtained. Followed by recrystallized from dichloromethane/hexanes, compound 13b (639 mg, yield: 85%) was obtained. Spectral data as follow: mp: 144-145° C.; M.W. 752.94; ¹H NMR (400 MHz, CDCl₃) δ 7.91 (d, J=7.6, 2H), 7.72 (d, J=7.6, 2H), 7.36-7.24 (m, 20H), 7.19 (t, J=7.6, 2H), 7.11 (t, J=8.4, 2H), 7.00 (s, 2H), 6.95 (s, 2H), 6.60 (t, J=7.5, 2H), 6.50 (d, J=8.4, 2H), 4.96 (s, 2H), 4.13 (s, 4H); ¹³C NMR (100 MHz, CDCl₃) δ 152.0, 148.6, 141.7, 139.1, 138.8, 136.2, 133.2, 132.4, 132.1, 131.9, 129.9, 128.6, 128.3, 128.2, 127.7, 127.6, 127.1, 126.8, 126.7, 123.2, 120.4, 116.4, 109.8, 107.2, 95.4, 87.1, 65.5, 47.4; TLC R_{f} 0.38 (CH₂Cl₂/hexanes, 1/3); HR-MS calcd for C₅₇H₄₀N₂: 752.3191, found: 752.3199; IR (KBr) v 3060 (w), 3029 (w), 2920 (w), 2849 (w), 2195 (w), 1600 (m), 1592 (m), 1573 (m), 1507 (s), 1494 (s), 1449 (s), 1382 (w), 1359 (w), 1323 (m), 1160 (w), 1120 (w), 1105 (w), 1080 (w), 1064 (w), 1004 (w).

### Example 9: Synthesis of Compound 14b (3,7-Bis(1-benzyl-2-indolyl)-5,5-spirofluorenyl-5H-dibenzo-[a,d]cycloheptene)

A 20 mL vacuum tube placed with a stir bar was dried by vacuum followed by back-filling with nitrogen gas. Compound 13b (753 mg, 1 mmol) was added to the tube and then dissolved in 2 mL of anhydrous tetrahydrofuran on an ice bath. A 1.66 M solution of n-Butyllithium in n-hexane (1.2 mL, 2 mmol) was added drop by drop to the tube, followed by return to room temperature. After reacting for 30 minutes at room temperature, 1.0 M zinc chloride solution (273 mg, 2 mmol zinc chloride dissolved in 2 mL of anhydrous tetrahydrofuran) was added to the tube. After reacting for 5 minutes, the solvent tetrahydrofuran was removed by rotator evaporation. Then, 2 mL of anhydrous toluene was added to the tube. After reacting for 1 hour at 120° C., the tube was cooled down to room temperature. Deionized water (1 ml) was then added to quench the reaction. The reaction mixture was then extracted by dichloromethane (3×20 mL). The combined extractant was then dried by adding anhydrous magnesium sulfate, followed by filtration and condensation with a rotary evaporator to obtain a crude product. The crude product was then purified by column chromatography using a mixture of dichloromethane and hexanes (1/3) as eluent and crude compound 14b was obtained. Followed by recrystallized from dichloromethane/hexanes, compound 14b (602 mg, yield: 80%) was obtained. Spectral data as follow: mp: 183-185° C.; M.W. 752.94; ¹H NMR (400 MHz, CDCl₃) δ 7.95 (d, J=7.6, 2H), 7.68 (d, J=8.0, 2H), 7.58-7.56 (m, 2H), 7.36-7.31 (m, 7H), 7.22-7.15 (m, 9H), 7.09-7.06 (m, 6H), 6.97 (s, 2H), 6.80-6.78 (m, 4H), 6.34 (s, 2H), 5.12 (s, 4H); ¹³C NMR (100 MHz, CDCl₃) δ 152.8, 141.9, 141.2, 138.7, 137.9, 137.7, 135.8, 132.9, 132.5, 130.0, 128.2, 128.1, 127.6, 127.0, 126.8, 126.6, 126.5, 125.9, 121.8, 120.4, 120.0, 110.5, 102.4, 65.9, 47.6; TLC R_{f} 0.46 (CH₂Cl₂/hexanes, 1/3); HR-MS calcd for C₅₇H₄₀N₂: 752.3191, found: 752.3182; IR (KBr) v 3059 (w), 3029 (w), 2954 (w), 2925 (w), 1680 (br), 1667 (br), 1659 (br), 1651 (br), 1644 (w), 1600 (m), 1494 (m), 1450 (s), 1401 (w), 1347 (w), 1313 (m), 1201 (br), 1159 (w), 1106 (br), 1077 (br), 1004 (w).

### Example 10: Synthesis of Compound 15b (3,7-Bis(1-benzyl-3-bromo-2-indolyl)-5,5-spirofluorenyl-5H-dibenzo[a,d]cycloheptene)

A 25 mL, two-necked, round-bottomed flask placed with a stir bar was dried by vacuum followed by back-filling with nitrogen gas. Compound 14b (753 mg, 1 mmol) was added to the flask, and then dissolved in 2 mL of dimethylformamide (DMF), followed by the addition of N-bromosuccinimide (NBS, 356 mg, 2 mmol). After reacting for 3 hours at room temperature, the reaction mixture was extracted by dichloromethane (3×20 mL). The combined extractant was then dried by adding anhydrous magnesium sulfate, followed by filtration and condensation with a rotary evaporator to obtain a crude product. The crude product was then purified by column chromatography using a mixture of dichloromethane and hexanes (1/3) as eluent and crude compound 15b was obtained. Followed by recrystallized from dichloromethane/hexanes, compound 15b (818 mg, yield: 90%) was obtained. Spectral data as follow: mp: 156-157° C.; M.W. 910.73; ¹H NMR (400 MHz, CDCl₃) δ 8.04 (d, J=7.6, 2H), 7.67 (d, J=7.2, 2H), 7.57-7.55 (m, 6H), 7.43-7.31 (m, 8H), 7.25-7.00 (m, 10H), 6.98 (s, 2H), 6.72 (d, J=7.2, 4H), 5.05 (s, 4H); ¹³C NMR (100 MHz, CDCl₃) δ 152.4, 141.7, 138.7, 137.6, 137.1, 136.4, 133.3, 132.3, 131.5, 130.2, 129.7, 128.9, 128.6, 128.5, 128.2, 127.7, 127.5, 127.4, 127.2, 127.1, 127.0, 126.8, 126.7, 125.9, 123.0, 120.6, 120.2, 119.3, 110.5, 91.3, 65.8, 48.2; TLC R_{f} 0.42 (CH₂Cl₂/hexanes, 1/3); HR-MS calcd for C₅₇H₃₈Br₂N₂: 908.1402, found: 908.1409; IR (KBr) v 3059 (w), 3029 (w), 2952 (w), 2924 (w), 2856 (w), 1718 (br), 1688 (br), 1590 (br), 1567 (w), 1495 (s), 1450 (s), 1398 (w), 1382 (w), 1346 (m), 1319 (m), 1263 (w), 1203 (w), 1154 (w), 1168 (w), 1087 (w), 1014 (w), 1002 (w).

### Example 11: Synthesis of Compound 16b (Chemical formula (2): IDOCP-STIF, 2,3,7,8-{N-Benzyl-12,17-dihydro-17,17-diphenyl-indeno[1,2-a]indenyl}-5,5-spirofluorenyl-5H-d ibenzo-[a,d]cycloheptene)

A 25 mL high pressure test tube placed with a stir bar was dried by vacuum followed by back-filling with nitrogen gas. Compound 15b (456 mg, 0.5 mmol) was added to the test tube, and then dissolved in anhydrous tetrahydrofuran (5 mL). A 1.66 M solution of n-Butyllithium (0.6 mL, 1 mmol) in hexane was added drop by drop to the test tube at −78° C. and then react for 30 minutes. Benzophenone (182 mg, 1 mmol) or anhydrous acetone (1 mmol) was added to the test tube at −78° C., followed by reacting for 30 minutes at the same temperature. The mixture was cooled down to room temperature and then reacts for 3 hours. Saturated aqueous sodium bicarbonate solution (10 mL) was added to quench the reaction. The tetrahydrofuran was removed by rotator evaporation and the reaction mixture was then extracted by dichloromethane (3×20 mL). The combined extractant was then dried by adding anhydrous magnesium sulfate, followed by filtration and condensation with a rotary evaporator to obtain a crude product. 30 mL of acetic acid and catalyst hydrochloric acid (12 N, 5 mol %) were added to the crude product, and the reaction mixture was refluxed for 2 hours. After cooling down to room temperature, saturated aqueous sodium bicarbonate solution (20 ml) was added to quench the reaction. The acetic acid was removed by rotator evaporation and the reaction mixture was then extracted by dichloromethane (3×20 mL). The combined extractant was then dried by adding anhydrous magnesium sulfate, followed by filtration and condensation with a rotary evaporator to obtain a crude product. The crude product was then purified by column chromatography using a mixture of dichloromethane and hexanes (1/5) as eluent and crude compound 16b was obtained. Followed by recrystallized from dichloromethane/hexanes, compound 16b (Chemical formula (2), 405 mg, yield: 75%) was obtained. Spectral data as follow: mp: 257° C. (DSC); M.W. 1081.35; ¹H NMR (400 MHz, CDCl₃) δ 8.00 (d, J=7.6, 2H), 7.72 (d, J=7.2, 2H), 7.62-7.60 (m, 4H), 7.39-7.36 (m, 8H), 7.31-7.26 (m, 6H), 7.25-7.19 (m, 6H), 7.15-7.09 (m, 10H), 7.00 (s, 6H), 6.84-6.82 (m, 6H), 6.39 (s, 2H), 5.16 (s, 4H); ¹³C NMR (100 MHz, CDCl₃) δ 152.8, 141.9, 141.2, 138.7, 137.9, 137.7, 135.8, 132.9, 132.5, 130.0, 129.0, 128.8, 128.7, 128.5, 128.3, 128.2, 128.1, 127.9, 127.6, 127.2, 127.0, 126.5, 125.9, 125.8, 121.8, 120.4, 120.0, 110.5, 102.4, 65.9, 47.6; Anal. Calcd for C₈₃H₅₆N₂ (MW: 1081.35): C, 92.19; H, 5.22; N, 2.59 Found: C, 92.50; H, 5.49; N, 2.70; TLC R_{f} 0.38 (CH₂Cl₂/hexanes, 1/5); HR-MS calcd for C₈₃H₅₆N₂: 1080.4443, found: 1080.4451; IR (KBr) v 3058 (w), 3025 (w), 2953 (w), 2922 (w), 2809 (w), 1599 (m), 1493 (m), 1450 (m), 1351 (m), 1199 (m), 1121 (br), 1089 (br), 1076 (br), 1019 (br), 1002 (w).

Measurement Data (thermal stabilities, photophysical properties and electrochemical properties) of the compounds of chemical formula (1) (INDCP-STIF) and chemical formula (2) (IDOCP-STIF) are shown in Table 1.

TABLE 1

| | INDCP-STIF | IDOCP-STIF |
|---|---|---|
| Compound | Chemical formula (1) | Chemical formula (2) |
| λₘₐₓ (εₘₐₓ × 10³)^{a} nm | 394 (29.0) | 369 (25.4) |
| PL λₘₐₓ nm (Φ_{f,} %)^{a} | 460,495 (81) | 461,502 (70) |
| T_{g} (° C.)/T_{d} (° C.) | 148/475 | 136/414 |
| Eₒₓ^{1/2} (V)^{b}/E_{red}^{1/2} (V)^{b} | +0.63/−2.04 | +0.72/−2.22 |
| Eg (eV)^{b} | 2.74 (2.67) | 2.95 (2.94) |

^{a}Measured in CH₂Cl₂.
^{b}Electrochemical data of materials for Eₒₓ measured in a CH₂Cl₂ containing 0.1M TBA(ClO₄) and for E_{red} measured in a THF containing 0.1M TBA(BF₄) using a glassy carbon as a working electrode and a Pt counter electrode with a scan rate of 100 mv s⁻¹, potentials are quoted with reference to the internal ferrocene standard (DIID-STIF: E_{1/2}^{ox} = 421 mV vs Ag/AgCl; DICBID-STIF: E_{1/2}^{ox} = 471 mV vs Ag/AgCl).
^{c} The band gap, E_{g}, is derived from the observed optical edge.

Regarding to the thermal stabilities, the decomposition temperature of the compound is measured by thermogravimetric analyzer (TGA). According to Table 1, the decomposition temperatures of chemical formula (1) and chemical formula (2) are both higher than 400° C., in particular, chemical formula (1) has the highest decomposition temperature of 475° C. It is attributable to that chemical formula (1) consists of the conjugated benzene rings. Although STIF system is coplanar with diindenoindacene system, STIF system has spiro fluorene fragment and diindeno-fused unit has double phenyl moieties (R′=Ph). Such molecular structure is stable. Moreover, the glass transition temperature (T_{g}) is measured by differential scanning calorimeter (DSC). The glass transition temperatures of chemical formula (1) and chemical formula (2) are both higher than 100° C. As mentioned above, because of the stability and rigidity of the structures, the glass transition temperatures (148 and 136° C.) are thus increased, especially the glass transition temperature of chemical formula (1). Overall, both chemical formula (1) and chemical formula (2) are materials with high thermal stability.

In addition, the maximum absorption wavelength of chemical formula (1) is 394 nm and that of chemical formula (2) is 369 nm. The absorption of chemical formula (1) is mainly effected by extended π-π resonance of the compound itself in ground state. The maximum absorption wavelength of chemical formula (2) is 25 nm blue shift of that of chemical formula (1). That is because pyrrole fragment would not resonate with other central fragments of chemical formula (2) in ground state, no effective intramolecular electron transfer is occurred. In other words, the absorption of chemical formula (2) is mainly effected by π-π resonance of individual indeno group and STIF fragment in ground state. Moreover, the maximum emission wavelengths of chemical formula (1) and chemical formula (2) are 460 nm and 461 nm, respectively. Chemical formula (1) and chemical formula (2) also have broader shoulder peaks at 495 nm and 502 nm, respectively. In other words, the emission of chemical formula (1) and chemical formula (2) are mainly effected by local π-π resonance of the compounds themselves in excited state. Moreover, when the polarity of the solvent is higher, the peak of chemical formula (2) at 502 nm in fluorescence spectrum is more obvious. The main reason is that pyrrole fragment would resonate with other central fragments of chemical formula (2) in excited state, so that intramolecular charge transfer is occurred.

Regarding to the electrochemical properties, oxidation potentials and reduction potentials of chemical formula (1) and chemical formula (2) are measured by way of cyclic voltammetry (CV). In the three-electrode system, glassy carbon electrode is used as a working electrode, platinum electrode is used as a counter electrode and Ag/Ag+ is used as a reference electrode. When measuring oxidation potentials, dichloromethane is used as a solvent and tert-butylammonium perchlorate (Bu₄N⁺ClO₄⁻) is used as an electrolyte. When measuring reduction potentials, tetrahydrofuran (THF) is used as a solvent and tetra-butylammonium tetrafluoroborate (Bu₄N⁺BF₄⁻) is used as an electrolyte. The oxidation potentials and reduction potentials of chemical formula (1) and chemical formula (2) are calibrated by using ferrocene as a standard. Both chemical formula (1) and chemical formula (2) have one set of reversible oxidation potentials, +0.63 V (chemical formula (1)) and +0.72 V (chemical formula (2)), respectively. It is attributed to that oxidation mainly occurs at diindeno-fused fragment of chemical formula (1) and pyrrole[3,2-e]-indancene-fused fragment of chemical formula (2). Moreover, both chemical formula (1) and chemical formula (2) have one set of reversible reduction potentials, −2.04 V (chemical formula (1)) and −2.22 V (chemical formula (2)), respectively. It is attributed to that reduction mainly occurs at seven-membered ring of cis-stilbene/fluorene spiro template in both compounds. Therefore, chemical formula (1) and chemical formula (2) are ambipolar molecular compounds which can stably provide an electron and receive an electron during carrier transport process. Hence, chemical formula (1) and chemical formula (2) not only can be light-emitting materials but also can be host materials of a luminescent layer or applied in organic thin film transistors.

In addition, the highest occupied molecular orbital energy level (E_{HOMO}) of chemical formula (1) is −5.43 eV and its lowest unoccupied molecular orbital energy level (E_{LUMO}) is −2.76 eV and band gap (Eg) is 2.74 eV. The highest occupied molecular orbital energy level (E_{HOMO}) of chemical formula (2) is −5.52 eV and its lowest unoccupied molecular orbital energy level (E_{LUMO}) is −2.57 eV and band gap (Eg) is 2.95 eV.

Moreover, charge mobilities of chemical formula (1) and chemical formula (2) are measured by time-of-flight analysis. The measured structure is ITO/PEDOT:PSS (25 nm)/Chemical formula (1) or Chemical formula (2)/MoOx (10 nm)/Al (130 nm). Herein, the thickness of chemical formula (1) is 3.8 μm and that of chemical formula (2) is 5.7 μm. And, the charge mobilities are measured under an electric field of E=2.5×105 V/cm. Herein, the hole mobility of chemical formula (1) is 0.9×10⁻⁴ cm²/Vs and that of chemical formula (2) is 3.4×10⁻⁴ cm²/Vs. The electron mobility of chemical formula (1) is 1.1×10⁻⁴ cm²/Vs and that of chemical formula (2) is 3.8×10⁻⁴ cm²/Vs. As mentioned above, chemical formula (1) and chemical formula (2) are ambipolar molecular compounds, and STIF is an electron acceptor. STIF can easily accept negative charges and makes them stable, so as to increase electron affinity of the compound itself. Therefore, hole carrier mobility of chemical formula (1) and chemical formula (2) can be decreased so that mobilities of hole carrier and electron carrier can be balanced.

The Device Efficiencies for Compounds (Chemical Formula: INDCP-STIF (1) and Chemical Formula (2): IDOCP-STIF) which are Used in Organic Electroluminescent Devices

Regarding to device fabrication, a vacuum deposition method or a spin-coating solution process method is used. Regarding to device configuration, poly(3,4-ethylenedioxythiophene) polystyrene sulfonate (PEDOT:PSS) used as an hole injection layer, 2,2′,2″-(1,3,5-benzinetriyl)-tris(1-phenyl-1-H-benzimidazole) (TPBI) used as an electron transport layer, a conductive glass with ITO used as an anode and LiF/Al used as a cathode integrate with chemical formula (1) and chemical formula (2) to form a basic device configuration. The obtained device efficiencies of each organic electroluminescent device are shown as in Table 2.

TABLE 2

| | | | | η_{c} (cd/A)/ | L_{max,} (L₂₀) |
|---|---|---|---|---|---|
| | Em, λₘₐₓ | Vₒₙ, V | ηₑₓₜ (%) | ηₚ (lm/W) | (cd/m²) |
| Chemical formula (1)/A^{a} | 484/512 (90) | 3.2 (5.3) | 0.83 | 2.2/1.3 | 3329 (832) |
| Chemical formula (2)/A^{a} | 508 (100) | 3.9 (7.1) | 0.70 | 1.9/1.1 | 881 (294) |
| Chemical formula (1)/A^{b} | 477/508 (77) | 3.3 (5.3) | 0.73 | 1.9/1.1 | 797 (196) |
| Chemical formula (2)/A^{b} | 504 (136) | 3.3 (8.4) | 0.01 | 0.14/0.1 | 28 |
| Chemical formula (1)/B^{b,c} | 471/501 (81) | 3.2 (6.0) | 2.8 | 6.3/3.3 | 5110 (1250) |
| Chemical formula (2)/B^{b,c} | 454 (70) | 3.7 (6.2) | 2.3 | 2.8/1.4 | 1411 (550) |
| Chemical formula (1)/C^{b,c} | 472 (80) | 3.0 (5.4) | 6.2 | 9.2/5.4 | 29800 (1660) |
| Chemical formula (1)/C^{b,c} | 465 (70) | 3.7 (6.1) | 5.0 | 7.5/5.4 | 34990 (1160) |

^{a}Configureation A: ITO/PEDOT:PSS (35 nm)/emitter (32 nm)/TPBI (40 nm)/LiF (1 nm)/Al; configureation B: ITO/PEDOT:PSS (35 nm)/CBP:emitter (32 nm)/TPBI (38 nm)/LiF (1 nm)/Al; configuration C: ITO/PEDOT:PSS(35 nm)/TAPC(10 nm)/BANE:emitter (32 nm)/BmPyPb (38 nm)/LiF (1 nm)/Al.
^{b}solution process.
^{c}compound 16a (15 wt %); compound 16b (3 wt %).

In addition, turn-on voltage (Vₒₙ), external quantum efficiency (ηₑₓₜ, %), device efficiency (η_{c}, cd/A), power efficiency (ηₚ, lm/W) and luminance (L₂₀) are measured at the current density of 20 mA/cm².

When the device is fabricated by vacuum evaporation, the device with chemical formula (1) has device efficiency of 2.2 cd/A, power efficiency of 1.3 lm/W, external quantum efficiency of 0.83% and luminance of 832 cd/m² measured at the current density of 20 mA/cm². On the other hands, the device with chemical formula (2) has device efficiency of 1.9 cd/A, power efficiency of 1.1 lm/W, external quantum efficiency of 0.73% and luminance of 294 cd/m² measured at the current density of 20 mA/cm². In addition, the energy gap between the HOMO of chemical formula (1) and that of PEDOT:PSS is 0.43 eV, and the energy gap between the HOMO of chemical formula (2) and that of PEDOT:PSS is 0.52 eV. Therefore, hole injection rate of device with chemical formula (1) is higher than that of device with chemical formula (2). Further, the energy gap between the LUMO of chemical formula (1) and that of the electron transport layer is 0.03 eV, and the energy gap between the LUMO of chemical formula (2) and that of the electron transport layer is 0.15 eV. Therefore, electron injection rate of device with chemical formula (1) is higher than that of device with chemical formula (2). From the above viewpoints, hole injection rate or electron injection rate of device with chemical formula (1) is higher than that of device with chemical formula (2), and recombination rate of hole carrier and electron in the luminescent layer with chemical formula (1) is higher than that in the luminescent layer with chemical formula (2). Thus, turn-on voltage of device with chemical formula (1) (3.2 V) is lower than that of device with chemical formula (2) (3.9 V). In addition, because the rate of injecting hole carrier and electron carrier in the luminescent layer with chemical formula (1) is higher than that of injecting hole carrier and electron in the luminescent layer with chemical formula (2), the recombination rate of hole carrier and electron carrier in the device with chemical formula (1) is also higher than that in the device with chemical formula (2). Accordingly, the whole efficiency of device with chemical formula (1) is superior to that of device with chemical formula (2).

Moreover, the device can also be fabricated by spin-coating, solution process. As shown in Table 2, comparing with the device fabricated by vacuum evaporation, the whole efficiency of the device with chemical formula (1) only decreases by 12-15%. However, the whole efficiency of the device with chemical formula (2) decreases by 99%. Accordingly, when the device is fabricated by solution process, stacking molecular arrangement formed in the device with chemical formula (1) is much more intact than that formed in device with chemical formula (2). Hence, the whole device efficiency of the device with chemical formula (1) fabricated by solution process is 88% of that of the device with chemical formula (1) fabricated by vacuum evaporation

Moreover, to improve the device efficiency, chemical formula (1) as a guest material is doped to 4,4′-bis(carbazol-9-yl)biphenyl (CBP) as a host material in the organic luminescent layer fabricated by solution process. As shown in Table 2, when chemical formula (1) is doped to CBP with a doping concentration of 10-15 wt %, the device has current efficiency of 6.3 cd/A, power efficiency of 3.3 lm/W, external quantum efficiency of 2.8% and luminance of 1250 cd/m² measured at the current density of 20 mA/cm². On the other hands, when chemical formula (2) is doped to CBP with a doping concentration of 3-5 wt %, the device has device efficiency of 2.8 cd/A, power efficiency of 1.4 lm/W, external quantum efficiency of 2.3% and luminance of 550 cd/m² measured at the current density of 20 mA/cm².

Injection rate of hole carrier from the hole injection layer or electron carrier from the electron transporting layer in the device with chemical formula (1) is higher than that in the device with chemical formula (2), so that turn-on voltage of the device with chemical formula (1) (3.2 ev) is lower than that of the device with chemical formula (2) (3.7 eV). More specifically, the energy gap between the LUMO of chemical formula (2) and that of CBP is only 0.07 eV, so electron from the electron transporting layer would move toward chemical formula (2) and CBP. Therefore, recombination of hole carrier and electron carrier is probably located between chemical formula (2) and CBP, and blue shift is thus shown in electro-luminescent spectrum.

When the device is fabricated by solution process, chemical formula (1) or chemical formula (2) doped to CBP can improve the whole device efficiency. For example, the whole device efficiency of the device with CBP doped with chemical formula (1) increases by 67-70% and that of the device with CBP doped with chemical formula (2) increases by 99%. That is because CBP can transfer its all electron and hole carriers to chemical formula (1) or chemical formula (2), the whole device efficiency of device with chemical formula (1) or chemical formula (2) are thus improved.

In addition, when BANE is used as a host material and chemical formula (1) or chemical formula (2) is used as a guest material, device in which the doping concentration of chemical formula (1) is 10 wt % has device efficiency of 9.2 cd/A, power efficiency of 5.4 lm/W, external quantum efficiency of 6.2% and luminance of 1660 cd/m² measured at the current density of 20 mA/cm². On the other hand, the device in which the doping concentration of chemical formula (2) is 5 wt % has device efficiency of 7.5 cd/A, power efficiency of 5.4 lm/W, external quantum efficiency of 5.0% and luminance of 1160 cd/m² measured at the current density of 20 mA/cm².

The spirally configured cis-stilbene/fluorene hybrid materials according to the embodiments are a series of organic fluorescent materials. The materials can increase the absorption in visible deep blue light area and emit strong sky-blue lights. When the materials integrated with PEDOT:PSS as a hole injection layer, TAPC as a hole transporting layer and TPBI or BmPyPb as an electron transporting layer, the materials can emit blue lights or bluish green lights.

In summary, in the spirally configured cis-stilbene/fluorene hybrid material and the organic electroluminescent device by using the same according to the present invention, two indenes or two pyrroles are fused with the spirally configured cis-stilbene/fluorene hybrid system, which acts as the core template. Herein, cis-stilbene with high geometric rigidity has high conjugation and fluorescence efficiency. When appended with the spiro fluorene group, the thermal stability of the whole material can be further increased. Also, due to such molecular configuration, intermolecular stacking does not occur easily in solid state or film so that fluorescence quenching effect caused by π-π stacking of the light emitting template can be prevented. In addition, both diindeno-fused molecular and dipyrrole-fused molecular possess high electron and hole transport properties and can improve the solubility in the solvent as well as the film forming ability. The most important is fluorescence property of the film is excellent. Therefore, the organic material of the present invention has excellent electronic, optical, and optoelectronic properties and thermal stability.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A spirally configured cis-stilbene/fluorene hybrid material, comprising a structure of the following General Formula (1), 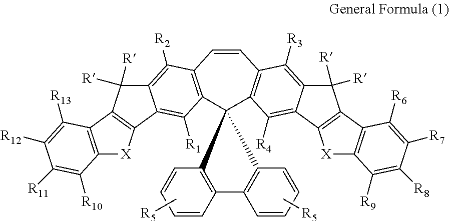
wherein, R′ is an alkyl group or represented by General Formula (2), X is represented by CR₃₆R₃₇ or NR₃₈, R₃₆ is represented by General Formula (3), R₃₇ is represented by General Formula (4), R₃₈ is represented by General Formula (5), 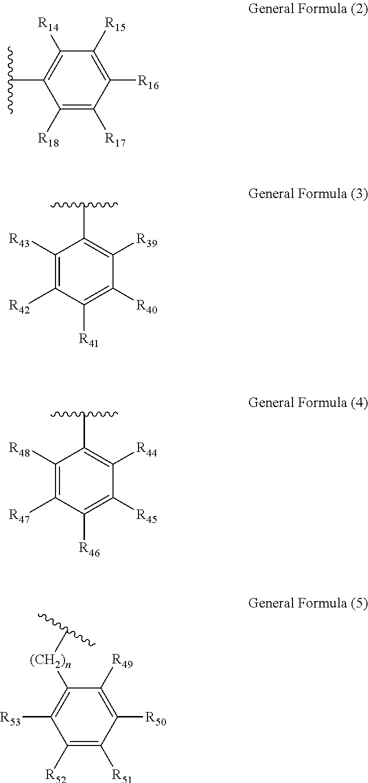
wherein, R₁ to R₄, R₆ to R₁₈ and R₃₉ to R₅₃ are each independently selected from the group consisting of a hydrogen atom, halogen atom, cyano group, alkyl group, cycloalkyl group, alkoxy group, amino group, haloalkyl group, thioalkyl group, silyl group and alkenyl group. R₅ is a hydrogen atom, tert-butyl group or naphthyl group, n is 0 or 1.

2. The spirally configured cis-stilbene/fluorene hybrid material of claim 1, wherein the alkyl group is selected from the group consisting of a substituted or unsubstituted straight-chain alkyl group with the carbon number of 1 to 6, and a substituted or unsubstituted branched-chain alkyl group with the carbon number of 3 to 6, the cycloalkyl group is a substituted or unsubstituted cycloalkyl group with the carbon number of 3 to 6, the alkoxy group is selected from the group consisting of a substituted or unsubstituted straight-chain alkoxy group with the carbon number of 1 to 6, and a substituted or unsubstituted branched-chain alkoxy group with the carbon number of 3 to 6, the amino group is selected from the group consisting of secondary amino group and tertiary amino group, the secondary amino group is an amino group having one aromatic ring substituent or having one C1-C6 straight-chain alkyl, branch-chain alkyl, or non-aromatic ring, the tertiary amino group is an amino group having two independent aromatic ring substituents or having two independent C1-C6 straight-chain alkyl, branch-chain alkyl, or non-aromatic ring, the haloalkyl group is selected from the group consisting of a substituted or unsubstituted straight-chain haloalkyl group with the carbon number of 1 to 6, and a substituted or unsubstituted branched-chain haloalkyl group with the carbon number of 3 to 6, the thioalkyl group is selected from the group consisting of a substituted or unsubstituted straight-chain thioalkyl group with the carbon number of 1 to 6, and a substituted or unsubstituted branched-chain thioalkyl group with the carbon number of 3 to 6, the silyl group is selected from the group consisting of a substituted or unsubstituted straight-chain silyl group with the carbon number of 1 to 6, and a substituted or unsubstituted branched-chain silyl group with the carbon number of 3 to 6, the alkenyl group is selected from the group consisting of a substituted or unsubstituted straight-chain alkenyl group with the carbon number of 2 to 6, and a substituted or unsubstituted branched-chain alkenyl group with the carbon number of 3 to 6.

3. The spirally configured cis-stilbene/fluorene hybrid material of claim 1, being represented by following chemical formula (1) or chemical formula (2).

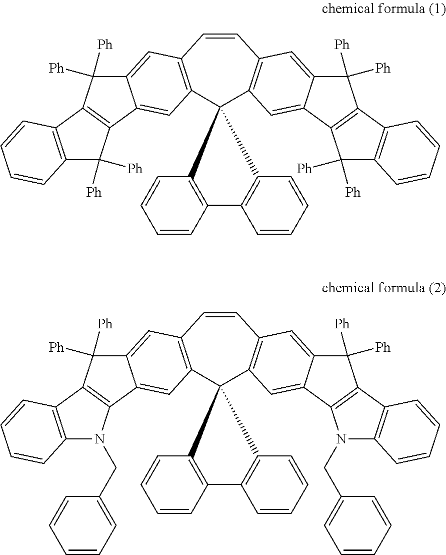

4. The spirally configured cis-stilbene/fluorene hybrid material of claim 1, having glass transition temperatures ranged from 136° C. to 148° C.

5. The spirally configured cis-stilbene/fluorene hybrid material of claim 1, having decomposition temperatures ranged from 414° C. to 475° C.

6. The spirally configured cis-stilbene/fluorene hybrid material of claim 1, having oxidation potentials ranged from 0.63V to 0.72V and reduction potentials ranged from −2.04V to −2.22V.

7. The spirally configured cis-stilbene/fluorene hybrid material of claim 1, having highest occupied molecular orbital energy level (E_{HOMO}) ranged from −5.43 eV to −5.52 eV and lowest unoccupied molecular orbital energy level (E_{LUMO}) ranged from −2.57 eV to −2.76 eV.

8. An organic electroluminescent device, comprising:
a first electrode layer;
a second electrode layer; and
an organic luminescent unit, deposited between the first electrode layer and the second electrode layer, wherein the organic luminescent unit has at least a spirally configured cis-stilbene/fluorene hybrid material as shown in General Formula (1), 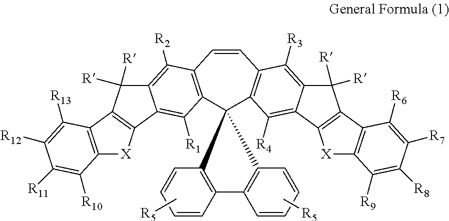
wherein, R′ is an alkyl group or represented by General Formula (2), X is represented by CR₃₆R₃₇ or NR₃₈, R₃₆ is represented by General Formula (3), R₃₇ is represented by General Formula (4), R₃₈ is represented by General Formula (5), 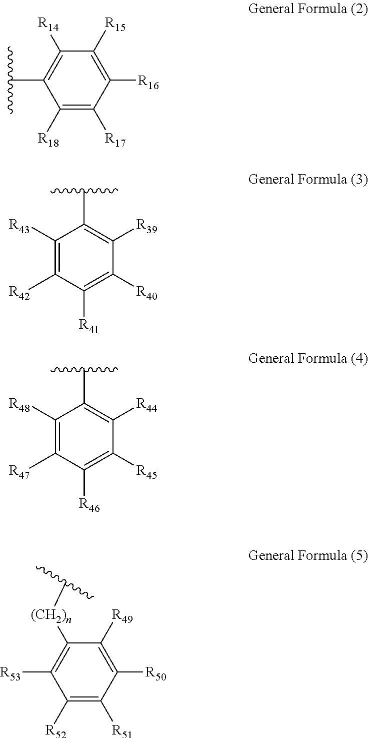
wherein, R₁ to R₄, R₆ to R₁₈ and R₃₉ to R₅₃ are each independently selected from the group consisting of a hydrogen atom, halogen atom, cyano group, alkyl group, cycloalkyl group, alkoxy group, amino group, haloalkyl group, thioalkyl group, silyl group and alkenyl group. R₅ is a hydrogen atom, tert-butyl group or naphthyl group, n is 0 or 1.

9. The organic electroluminescent device of claim 8, wherein the alkyl group is selected from the group consisting of a substituted or unsubstituted straight-chain alkyl group with the carbon number of 1 to 6, and a substituted or unsubstituted branched-chain alkyl group with the carbon number of 3 to 6, the cycloalkyl group is a substituted or unsubstituted cycloalkyl group with the carbon number of 3 to 6, the alkoxy group is selected from the group consisting of a substituted or unsubstituted straight-chain alkoxy group with the carbon number of 1 to 6, and a substituted or unsubstituted branched-chain alkoxy group with the carbon number of 3 to 6, the amino group is selected from the group consisting of secondary amino group and tertiary amino group, the secondary amino group is an amino group having one aromatic ring substituent or having one C1-C6 straight-chain alkyl, branch-chain alkyl, or non-aromatic ring, the tertiary amino group is an amino group having two independent aromatic ring substituents or having two independent C1-C6 straight-chain alkyl, branch-chain alkyl, or non-aromatic ring, the haloalkyl group is selected from the group consisting of a substituted or unsubstituted straight-chain haloalkyl group with the carbon number of 1 to 6, and a substituted or unsubstituted branched-chain haloalkyl group with the carbon number of 3 to 6, the thioalkyl group is selected from the group consisting of a substituted or unsubstituted straight-chain thioalkyl group with the carbon number of 1 to 6, and a substituted or unsubstituted branched-chain thioalkyl group with the carbon number of 3 to 6, the silyl group is selected from the group consisting of a substituted or unsubstituted straight-chain silyl group with the carbon number of 1 to 6, and a substituted or unsubstituted branched-chain silyl group with the carbon number of 3 to 6, the alkenyl group is selected from the group consisting of a substituted or unsubstituted straight-chain alkenyl group with the carbon number of 2 to 6, and a substituted or unsubstituted branched-chain alkenyl group with the carbon number of 3 to 6.

10. The organic electroluminescent device of claim 8, being represented by following chemical formula (1) or chemical formula (2).

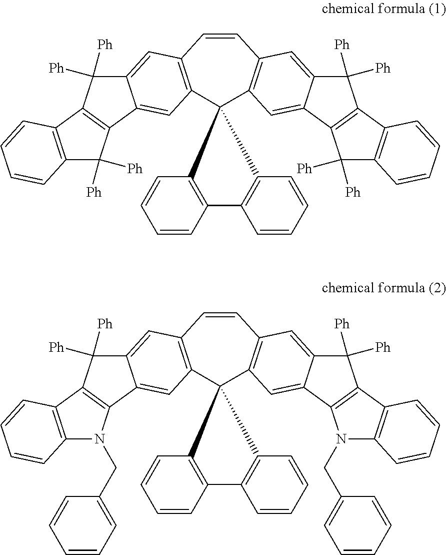

11. The organic electroluminescent device of claim 8, wherein the organic luminescent unit comprises an organic luminescent layer.

12. The organic electroluminescent device of claim 11, wherein the organic luminescent unit further comprises a hole transport layer and an electron transport layer, and the organic luminescent layer is deposited between the hole transport layer and the electron transport layer.

13. The organic electroluminescent device of claim 11, wherein the organic luminescent unit further comprises a hole injection layer, a hole transport layer, an electron transport layer and an electron injection layer, and the hole transport layer, the organic luminescent layer and the electron transport layer are sequentially deposited between the hole injection layer and the electron injection layer.

14. The organic electroluminescent device of claim 11, wherein the organic luminescent layer comprises the spirally configured cis-stilbene/fluorene hybrid material.

15. The organic electroluminescent device of claim 11, wherein the organic luminescent layer comprises a host material and a guest material, and the guest material comprises the spirally configured cis-stilbene/fluorene hybrid material.

16. The organic electroluminescent device of claim 15, wherein the content of the guest material in the organic luminescent layer is between 3 wt % to 15 wt %.
